(19) United States
(12) Patent Application Publication
(10) Pub. No.: US 2022/0243996 A1
(43) Pub. Date: Aug. 4, 2022

(54) COOLING DEVICE

(71) Applicant: Miba eMobility GmbH, Laakirchen (AT)

(72) Inventors: Stefan GAIGG, Gmunden (AT); Franz POEHN, Pettenbach (AT); Alfred STAUDINGER, Innerschwand am Mondsee (AT); Christoph WILFLING, Linz (AT)

(73) Assignee: Miba eMobility GmbH, Laakirchen (AT)

(21) Appl. No.: 17/607,179

(22) PCT Filed: Apr. 28, 2020
(86) PCT No.: PCT/AT2020/060172

§ 371 Date: Oct. 28, 2021

(30) Foreign Application Priority Data
May 6, 2019 (AT) A50405/2019

(51) Int. Cl. F28D 15/04; F28D 15/02; H01M 10/6552; H01M 10/613; H01M 10/6554

(52) U.S. Cl. CPC F28D 15/046; F28D 15/0233; H01M 10/6554; H01M 10/613; H01M 10/6552

(57) ABSTRACT

A cooling device includes a sleeve of at least one single-layer or multi-layer film, which forms an interior, in which a working medium and at least one vaporization element for converting at least part of the working medium from the liquid to the gaseous state are contained, wherein at least one mat made of/comprising inorganic fibers is arranged between the vaporization element and the sleeve, and the vaporization has knob-shaped structural elements and/or is formed as a foam element.

The invention relates to a cooling device comprising a sleeve of at least a single-layer or multi-layer film, which forms an interior, in which a working medium and at least one vaporization element are contained for converting at least part of the working medium from the liquid into the gaseous state.

Moreover, the invention relates to a rechargeable battery having a storage module or multiple storage modules for electrical energy and at least one cooling device for cooling or controlling the temperature for the at least one storage module.

The service life and effectiveness as well as the safety of a rechargeable battery for e-mobility depend, among other factors, on the temperature during operation. For this reason, various concepts have been suggested for the cooling and/or temperature control of the rechargeable batteries. These concepts can be divided into essentially two types, namely air cooling and water cooling and/or in general cooling with liquids.

For water cooling, cooling bodies in which at least one coolant channel is formed are used. These cooling bodies are arranged between the individual modules of the rechargeable battery or on the modules. In this regard, a module is an individual unity of the rechargeable battery, i.e. not obligatorily just a cell.

It is further known from the prior art that so-called heat pipes are used for heat transfer.

DE10 2008 054 958 A1 describes a temperature control system for controlling the temperature of at least one rechargeable battery of a vehicle with at least one heat transfer device for thermal connection of the battery to at least one heat source and/or heat sink arranged in the vehicle. The heat transfer device comprises at least one heat contact zone for releasably thermally contacting the battery and at least one heat pipe for heat transfer.

In simple terms, a heat pipe is a self-contained system in a substantially pipe-shaped or flat housing that has a fluid in its inside that is close to its boiling point at operating temperature due to the prevailing pressure. If the heat pipe is heated in a partial area, the fluid changes to the gaseous phase, to flow in the direction of a cooler area in the interior of the heat pipe, condense there and flow back into the warmer area along the inner walls of the housing of the heat pipe. In the course of this (heat) transfer process, the heat pipe extracts heat from its surroundings in a vaporization area and supplies this heat to the surroundings of the condensation area of the heat pipe.

The present invention is based on the object of creating an improved system for cooling a rechargeable battery, i.e. an accumulator.

The object of the invention is achieved by means of the initially mentioned cooling device, in which at least one mat made of or comprising inorganic fibers is arranged between the vaporization element and the sleeve, and in which the vaporization element has knob-shaped structural elements and/or is formed as a foam element.

The object of the invention is further achieved by means of the initially mentioned rechargeable battery, in which the cooling device is provided in accordance with the invention.

In this regard, it is advantageous that a simple structure of the cooling device is possible. Due to the knob-shaped structural elements, the vertical heat transfer can be made possible, meaning in particular the primary outward transfer of the heat originating from the storage cells of the rechargeable battery. The removal of the heat from the system then takes place in the horizontal direction, involving the mat made of or comprising the inorganic fibers, into “cold” regions of the cooling device, in which the heat exchange and condensation of the working medium happening in the course of this take place. Due to the chosen structure of the cooling device, it can be produced by means of the easy insertion of the at least one mat made of or comprising the inorganic fibers and the vaporization element. Thus, a cost-effective embodiment of the cooling device is also achievable.

According to an embodiment variant of the cooling device, it may be provided that multiple vaporization elements are arranged in the interior of the sleeve. By avoiding only a single vaporization element, which extends approximately over the entire areal extent of the cooling device, more flexibility can be integrated into the cooling device, so that it can better adapt to uneven surfaces. With this, the effectiveness of the cooling device can in turn be improved. For the further simplification of the production of the cooling device and for reducing the production cost, it may be provided that the vaporization element or the vaporization elements is or are each made of a polymer material and are formed in one piece. The vaporization elements can thus be produced off-tool, so that no post-processing is necessary. Moreover, the material mix of the cooling device can thereby be reduced as the cooling device can essentially consist only of plastics and the at least one mat made of or comprising the inorganic fibers.

For a further improvement of the horizontal heat transfer, it may be provided according to a further embodiment variant that a mat made of/comprising inorganic fibers is arranged between the multiple vaporization elements, as well. The arrangement of multiple vaporization elements also has the advantage that the vertical heat transfer can thereby be improved.

For improving the efficiency of the heat transfer, it may be provided according to a different embodiment variant that the knob-shaped structural elements are formed to be porous, in particular are formed of glass elements or ceramic elements or sintered copper elements according to a further embodiment variant. Thereby, an accordingly large vaporization chamber within the cooling device can be provided. Additionally, the capillary fluid transport within the cooling device can be improved thereby. Furthermore, a spacing function between the front and rear side of the sleeve can also be provided thereby, so that the interior is not partially reduced even at lower temperatures. Due to the improved heat transfer, the temperature in the interior of the cooling device can be kept relatively low, whereby the internal pressure in the interior is also relatively low and therefore the pressure difference between the outside and the inside is greater.

According to a further embodiment variant of the cooling device, it may be provided that the vaporization element has a holding element, in which the knob-shaped structural elements are held. Because of the design of the knob-shaped structural elements as individual elements, different arrangements of such structural elements can be easily realized, whereby the modularity of the cooling device can be increased. With that, an improved adaptation of the cooling device to the respective cooling task is achievable. Additionally, the risk of breakage of the cooling device components made of glass can also be reduced thereby as the stiffness of the cooling device can be reduced by this. This, in turn, allows a better adaptability of the cooling device to different surface qualities, whereby the contact of the cooling device with objects to be cooled, and thus the effectiveness of the cooling, can be improved.

According to an embodiment variant, the holding element is preferably plate-shaped and formed of a polymer material for this purpose, whereby the mechanical filling of the holding element with the knob-shaped structural elements can be improved. Moreover, this can achieve a weight reduction as compared to other materials.

According to a further embodiment variant of the cooling device, it may be provided that the polymer material is a hydrophilic plastic film, whereby the capillary pumping effect of the mat made of or comprising the inorganic fibers can be supported better.

For further improvement of the formation of capillary channels in the interior of the cooling device, it may be provided according to a further embodiment variant of the cooling device that at least one plastic element made of a hydrophilic polymer material is arranged between the sleeve and the vaporization element.

For improving the mechanical stability of the cooling device, it may be provided according to an embodiment variant of the cooling device that at least one metal element is arranged between the sleeve and the vaporization element. In this regard, their arrangement in the interior has the advantage that the chemical stress of the metal element is predictable and thus more controllable in comparison to its arrangement at an outside of the cooling device.

According to a different embodiment variant of the cooling device, it may be provided that the sleeve is at least partially formed by a composite film made of at least one polymer material and a metal film. In this regard, it is advantageous that the heat transfer element can be easily produced from one film or two films connected to one another. Thus, the flexibility of the cooling device with regard to its geometry can be increased. Using a composite film allows, on the one hand, achieving a simplification of making the interior sealable by means of plastic welding. On the other hand, the metal film allows achieving a better heat distribution across the surface of the cooling device, whereby its efficiency can be improved. By the better heat distribution due to the improved heat conductivity of the films, moreover, hotspots can be better prevented during operation of the cooling device. Besides this, the cooling device can hence also be provided with a barrier function.

variant provides that the sleeve is formed of two films connected to one another. It is thereby possible to easily arrange the individual components of the cooling device on top of one another and to afterwards connect the two films to one another. Hence, the degree of automation of the production of the cooling device can also be increased.

According to an embodiment variant of the cooling device, it may additionally be provided that the two films are different from each other. This allows improving the thermal properties of the cooling device by the respective film being better adaptable to its purpose of application. For example, the film contacting a cell of the rechargeable battery may be formed to be thinner than the other film of the sleeve.

According to further embodiment variants of the cooling device, it may be provided that it is designed to be plate-shaped or with an L-shaped cross-section, whereby it can be installed more easily into a rechargeable battery.

For a more compact embodiment of the rechargeable battery, it may be provided according to an embodiment variant of the rechargeable battery that the cooling device is at least partially arranged between the two storage modules, wherein a further cooling device, which contacts the cooling device, is arranged between the storage modules.

According to a different embodiment variant of the rechargeable battery, it may also be provided that the multiple storage modules are connected to one another via at least one busbar, wherein the cooling device is arranged so as to contact the busbar.

For the purpose of better understanding of the invention, it will be elucidated in more detail by means of the figures below.

These show in a simplified schematic representation:

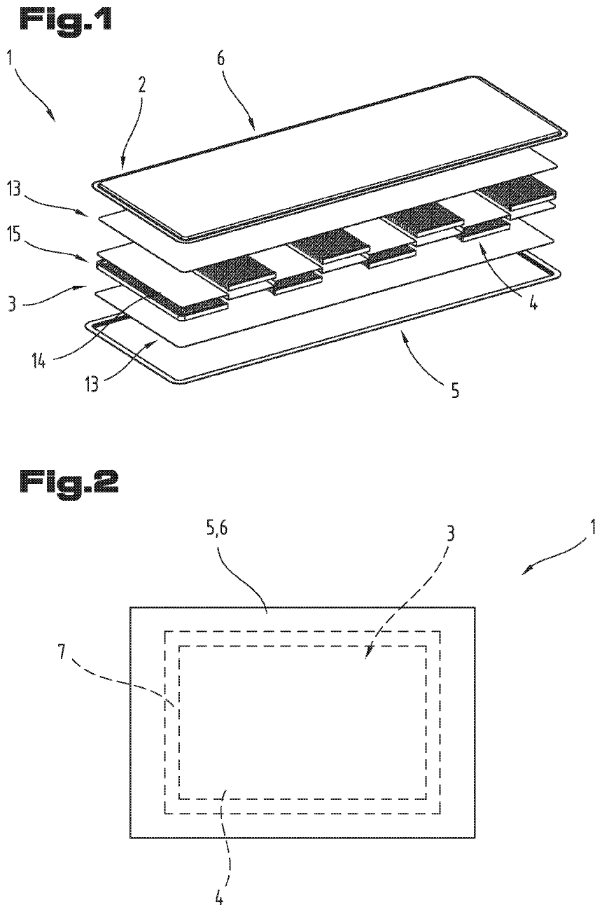

FIG. 1 an embodiment variant of the cooling device in an exploded view;

FIG. 2 an embodiment variant of the cooling device in a top view;

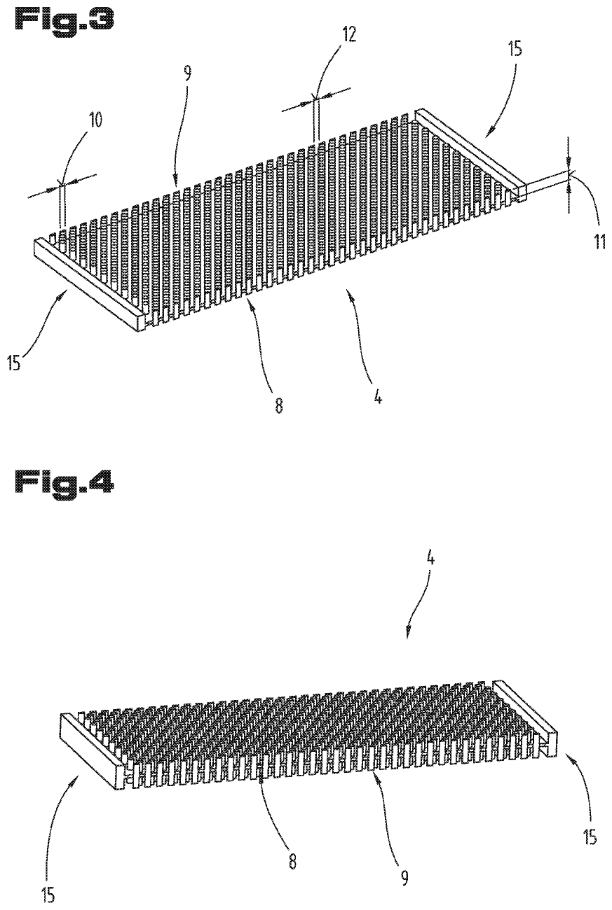

FIG. 3 an embodiment variant of a vaporization element;

FIG. 4 a different embodiment variant of a vaporization element;

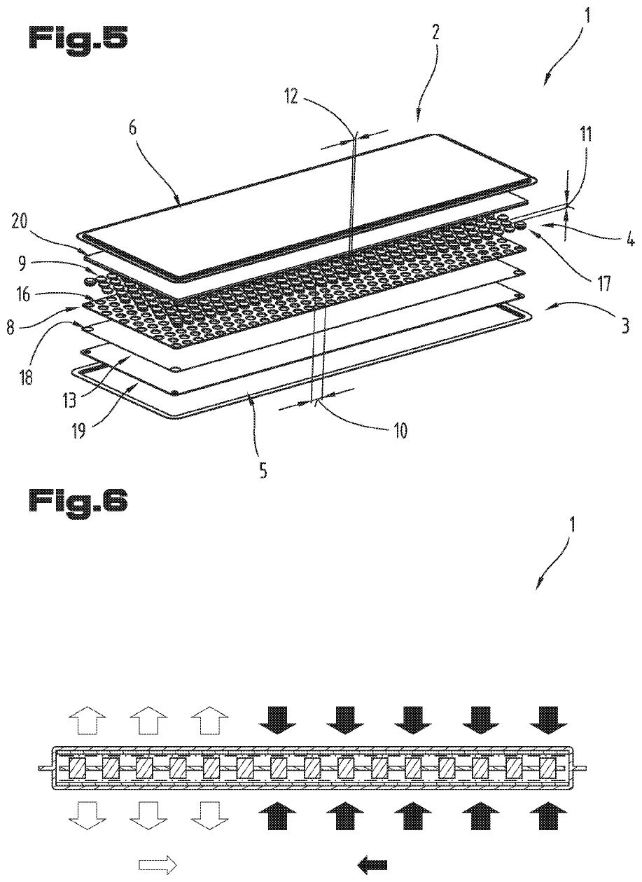

FIG. 5 an embodiment variant of the cooling device in an exploded view;

FIG. 6 a schematic representation of the heat transfer inside a plate-shaped cooling device;

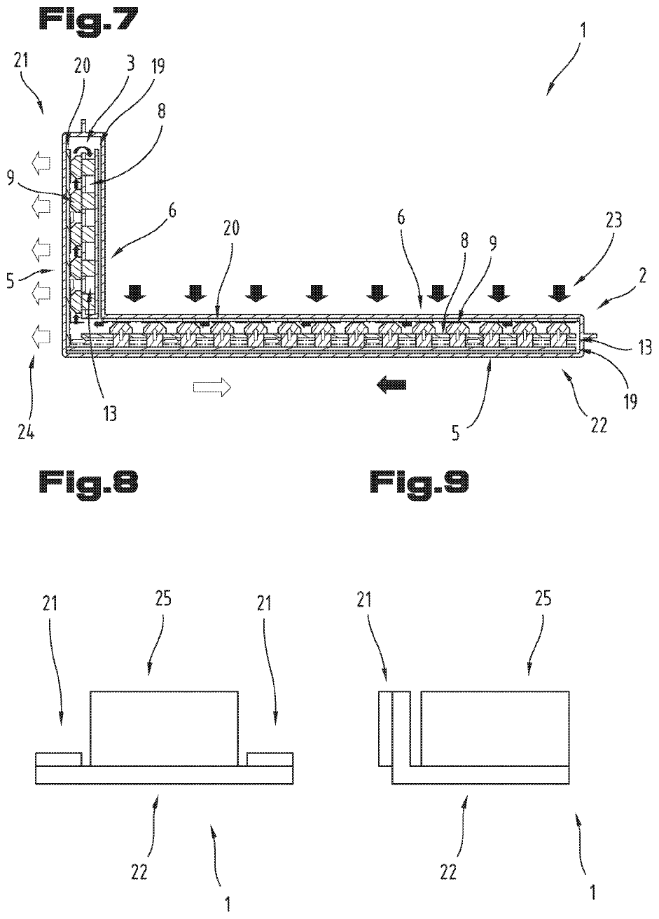

FIG. 7 a schematic representation of the heat transfer inside an L-shaped cooling device;

FIG. 8 the arrangement of a cooling device on a rechargeable battery;

FIG. 9 an alternative embodiment of a cooling device on a rechargeable battery;

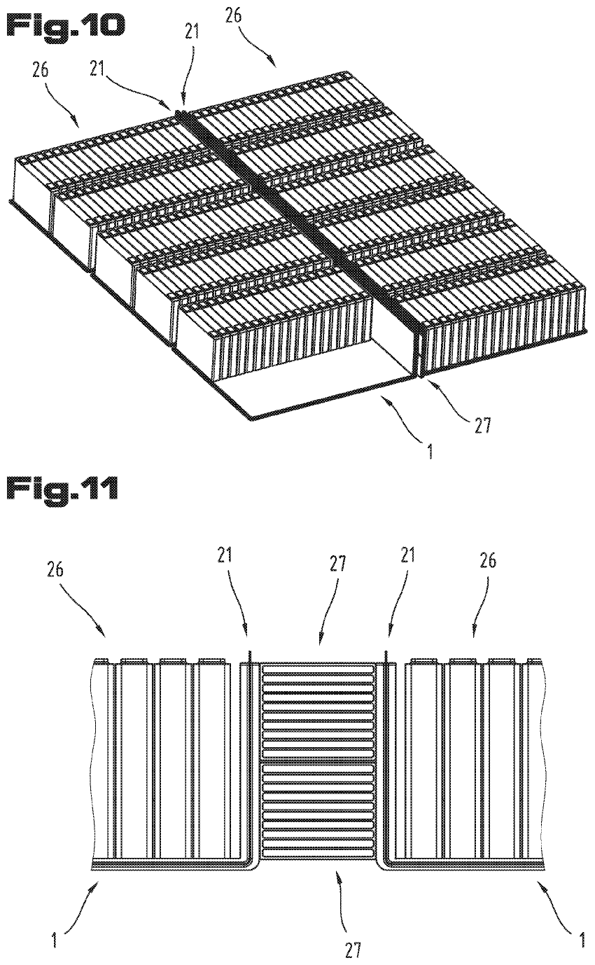

FIG. 10 an arrangement with multiple storage cells for electrical energy, cooled by the cooling device, and with a secondary cooler;

FIG. 11 an alternative embodiment of the secondary cooler;

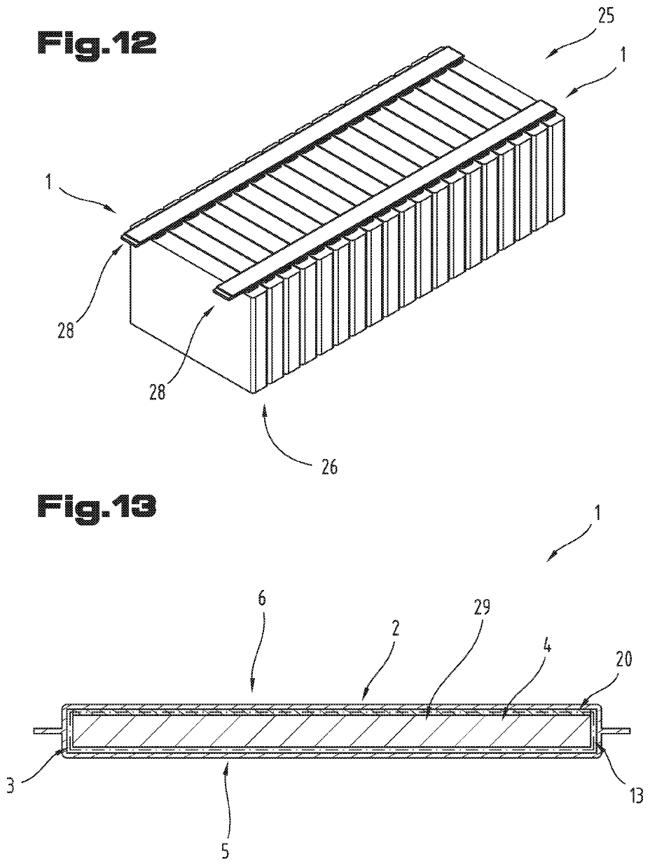

FIG. 12 a rechargeable battery with a cooled busbar;

FIG. 13 a further embodiment variant of the cooling device in a sectional side view.

First of all, it is to be noted that in the different embodiments described, equal parts are provided with equal reference numbers and/or equal component designations, where the disclosures contained in the entire description may be analogously transferred to equal parts with equal reference numbers and/or equal component designations. Moreover, the specifications of location, such as at the top, at the bottom, at the side, chosen in the description refer to the directly described and depicted figure and in case of a change of position, these specifications of location are to be analogously transferred to the new position.

FIG. 1 shows a first embodiment variant of the cooling device 1. The cooling device 1 comprises a sleeve 2 forming an interior 3. At least one vaporization element 4 is arranged in the interior 3. Moreover, a working medium which is not depicted is contained in the interior 3. The working medium may, for example, be water. However, other liquids or gases may also be used as long as the requirement is met that the working medium can at least partly vaporize and then condense again during the operation of the cooling device 1, to hence achieve cooling of the object equipped with the cooling device 1.

The sleeve 2 consists of or comprises at least one film made of a polymer material or comprising a polymer material.

A polymer material, within the meaning of the invention, is a material made of polymers which are made from monomers or oligomers by means of known reactions. In particular, the polymer material is a plastic made of organic polymers.

It is possible that the sleeve 2 consists of only a single film, which is folded on one side and is welded or glued on the other sides in order to form the interior 2. According to a preferred embodiment variant, however, the sleeve 2 has a first film 5 and a second film 6. The first film 5 may form a base part and the second film 6 may form a cover part, or vice versa.

The film or the first and the second film 5, 6 may generally be formed to have one layer, for example consist of a plastic film which is selected from a group consisting of PE, PP, POM, PA, PPS, crosslinked polyolefins, thermoplastic elastomers on ether basis/ester basis, styrene block copolymers, silicone elastomers.

According to an embodiment variant, a composite film is preferably used as the film or as the first and the second film 5, 6, which composite film is formed of at least one polymer material and at least one metal film. In this regard, the polymer material may be a plastic selected from a group consisting of PE, PP, POM, PA, PPS, crosslinked polyolefins, thermoplastic elastomers on ether basis/ester basis, styrene block copolymers, silicone elastomers. The polymer material preferably is PE or PP or PA6.

The metal film may, for example, be an aluminum film or a copper film or a gold film or a silver film. It is also possible to use a metalized plastic film instead of a metal film, wherein the plastic film is preferably selected from the aforementioned group of plastics.

The metal film may form the outer or the inner layer of the composite film. In this regard, the inner layer is that layer which faces the interior. However, mixed variants are also possible. Accordingly, the first film 5 may have the metal film on the inside and the second film 6 may have the metal film on the outside, or vice versa.

Embodiments of the composite film having more than two layers, for example having three layers or four layers, are also possible. In this case, at least one of the further layers may consist of a polymer material, in particular a plastic selected from aforementioned the group.

In the case of embodiments of the composite film having more than two layers, the metal layer may be arranged between two layers, each made of a polymer material. In this regard, one layer is preferably composed of a so-called sealing film, via which the first film 5 is connected to the second film 6. It is preferred that the two sealing films partially contact one another directly, thus forming the innermost layers of the composite film, facing the interior.

The metal film can have a layer thickness of between 7 μm and 50 μm in particular of between 10 μm and 20 μm.

The layer of the polymer material, in particular the plastic, can have a layer thickness of between 10 μm and 200 μm. If the composite film has multiple such layers, each of these layers may have a layer thickness selected from this range.

The composite film may also have an enforcement layer. Preferably, the enforcement layer comprises a, or consists of, a fiber reinforcement. The fiber reinforcement is preferably formed as a separate layer, which is arranged between two layers of polymer material. However, the fiber reinforcement may also be arranged within a layer of polymer material. The polymer material preferably is a plastic film, in particular selected from the aforementioned group of plastics.

The fiber reinforcement can be formed of fibers and/or threads, which are selected from a group comprising or consisting of glass fibers, aramid fibers, carbon fibers, mineral fibers such as basalt fibers, natural fibers such as hemp, sisal, and combinations thereof.

By means of the enforcement layer, an improved stiffness and stability can be achieved. The composite film can thus further have a reduced thermal expansion, which leads to fewer stresses in the cooling device 1 in case of temperature changes.

The first and the second film 5, 6 are preferably used having the same areal extent (in each case as viewed from the top).

According to a different embodiment variant, it may be provided that the first film 5 is different from the second film 6. For example, one of the two films 5, 6 may have a thinner sealing film than the other one of the two films 5, 6.

As mentioned before, the film or the first and the second film 5, 6 may be welded to one another. For this purpose, a welding frame 7 made of a plastic, in particular selected from one of the aforementioned plastics, may be used, which welding frame 7 has an areal extent that is greater than the areal extent of the interior 2 but smaller than the areal extent of the cooling device 1 (in each case as viewed from the top), as can be seen in FIG. 2 showing an embodiment variant of the cooling device 1 in a top view. In this regard, said welding frame 7 is arranged between the film parts when using only one film or between the first and second films 5, 6. Due to the welding, the welding frame 7 bonds with the film parts or the first and the second film 5, 6 and, together with it/them, forms a sealed weld seam. It is thus possible to form the composite film(s) to be thinner and to thereby improve the thermal properties of the cooling device 1, as the greater layer thickness is provided by the welding frame 7 for producing the sealed weld seam.

According to a further embodiment variant, it may be provided that said film and/or the first and/or the second film 5, 6 are preformed in order to thus be able to better form the interior 3 and/or in order to thus improve the assembly of the cooling device 1. For this purpose, said film and/or the first and/or the second film 5, 6 may be formed to be at least approximately tub-shaped so the at least one vaporization element 4 can be inserted better. The preforming may take place, for example in a hydraulic or pneumatic press, in particular at an increased temperature.

FIG. 3 shows a first embodiment variant of the vaporization element 4 in an oblique view. The vaporization element 4, which is used in particular in the cooling device 1 according to FIG. 1, is formed to be plate-shaped and has a holding element 8, on which multiple knob-shaped structural elements 9 are arranged. In this regard, the knob-shaped structural elements 9 project beyond the surface of the holding element 8 in one direction, i.e. upwards or downwards.

FIG. 4 shows an embodiment variant of this vaporization element 4. The only difference to the one according to FIG. 3 in this regard is that the knob-shaped structural elements 9 project beyond the particularly plate-shaped holding element 8 both upwards and downwards.

The vaporization element 4 according to FIG. 3 and/or FIG. 4 is preferably made of a polymer material, in particular of an organic plastic. The organic plastic may be selected from the aforementioned group of plastics.

In these embodiment variants of the vaporization element 4, it may further be provided that the holding element 8 and the structural elements 9 are formed as one piece, in particular off-tool.

In these embodiment variants of the vaporization element 4, the knob-shaped structural elements 9 are designed to be at least approximately cylindrical, in particular cylindrical. They may have a diameter 10 which is selected from a range of between 1 mm and 10 mm, in particular from a range of between 1 mm to 3 mm.

Moreover, they may have a height 11 which is selected from a range of between 1 mm and 10 mm, in particular from a range of between 1 mm and 5 mm. In this regard, the height 11 is measured from the surface of the holding element 8. The holding element itself may have a thickness in the direction of the height 11, which is selected from a range of between 0.1 mm and 3 mm, in particular from a range of between 0.3 mm and 1.5 mm.

In the case of the embodiment variant of the vaporization element 4 according to FIG. 4, the height 11 of the structural elements 9 may be selected from the mentioned range for the height 11, both on the upper side and on the bottom side of the holding element 8. In this regard, the knob-shaped structural elements 9 may have the same height 11 on both sides or may have one side projecting further beyond the holding element 8 than the other side.

A maximum distance 12 between directly adjacent structural elements 9 may be selected from a range of between 0.5 mm and 20 mm, in particular from a range of between 1 mm and 10 mm.

The knob-shaped structural elements 9 may be arranged in rows and columns, as can be seen in FIGS. 3 and 4. However, they can also have a different geometrical arrangement on the holding element 9.

The knob-shaped structural elements 9 serve, in particular, to form a gas space in the interior 3 of the cooling device 1.

The vaporization element 4 may have a rectangular base area. However, other geometries are also possible, for example a square one, a triangular one, etc.

In order to increase the heat conductivity, a thermally conductive plastic may be used for the production of the holding element 8 and/or of the knob-shaped structural elements 9. This may be achieved, for example, in that heat conductivity particles, such as particles of hexagonal boron nitride or of graphite, are added to the base polymer.

As can be seen in FIG. 1, at least one mat 13 made of or comprising inorganic fibers is arranged between the sleeve 2 and the vaporization element in the cooling device 1. In the specific exemplary embodiment shown, one such mat 13 is arranged on each side of the vaporization element 4, i.e. Above and below the vaporization element 4. The mat(s) 13 may be designed to have one layer or multiple layers. The purpose of the mat(s) 13 is to provide the horizontal heat conduction, as has been previously explained.

According to an embodiment variant of the cooling device, which is also shown in FIG. 1, at least one further mat 14 made of or comprising inorganic fibers may be arranged if more than one vaporization element 4 is present in the interior 3 of the cooling device 1. This further mat 14 may be arranged so as to run in a meandering pattern, so that the vaporization elements 4 alternately contact the top or the bottom of this further mat 14, as it results from the representation of the cooling device in FIG. 1.

The mat 13 and the further mat 14 may consist of inorganic fibers. The fibers may be selected from a group comprising or consisting of glass fibers, mineral fibers, such as basalt fibers, etc. It is particularly preferred to use glass fibers. The glass fibers used here are, in particular, glass fibers in the narrower sense, i.e. with a silicate structure, for example quartz glass and/or glass which was produced with SiO₂ as the main constituent.

The mats 13 and the further mat 14 may be a non-crimp fabric, a knitted fabric, a non-woven fabric, a woven fabric, etc., made of fibers.

The mat(s) 13 and/or the further mat 14 may have mass per unit area of between 30 g/m² and 800 g/m², in particular between 50 g/m² and 600 g/m². Moreover, the mat(s) 13 and/or the further mat 14 may be formed to have one layer or multiple layers.

The mat(s) 13 and/or the further mat 14 may consist of 80%, in particular at least 90%, preferably at least 99.9%, inorganic fibers.

Moreover, the mat(s) 13 and/or the further mat 14 is/are preferably cleaned before being used in the cooling device, for example by means of a solvent or thermally.

The mat(s) 13 and/or the further mat 14 preferably directly abut on the knob-shaped structural elements 9. However, it may also be provided that the fibers are at least partially embedded in a matrix, in particular an open-pore matrix, for example made of a plastic.

According to a further embodiment variant, it may be provided that the vaporization element 4 or that the vaporization elements 4 have strip-shaped elements 15. In this regard, this and/or these may form the aforementioned welding frame 7 (FIG. 2) and/or a support frame, according to a further embodiment variant of the cooling device 1. In the case of multiple vaporization elements 4, the strip-shaped elements 15 are arranged, in this regard, such that the welding frame 7 is formed when all vaporization elements 4 are arranged so as to lie next to one another in one plane.

Further and possibly independent embodiment variants of the cooling device 1 are shown in FIGS. 5 to 7, wherein again, equal reference numbers and/or component designations are used for equal parts as in FIGS. 1 through 4. In order to avoid unnecessary repetitions, the detailed description regarding the preceding FIGS. 1 through 4 is pointed out and/made reference to, in particular the mat 13, the sleeve 2, the embodiments of the arrangement of the knob-shaped structural elements 9, etc.

The cooling device 1 according to FIG. 5 again has a sleeve 2, which is in particular formed by the first film 5 and the second film 6, and which forms the interior 3 accommodating the working medium, a mat 13 with at least one layer made of or comprising inorganic fibers, in particular glass fibers, as well as at least one vaporization element 4. In this regard, the mat 13 made of or comprising inorganic fibers is arranged between the vaporization element 4 and the first film 5. Like in the preceding embodiment variants of the cooling device 1, the vaporization element 4 serves to convert at least part of the working medium from the liquid into the gaseous state.

The vaporization element 4 comprises the, in particular plate-shaped, holding element 8 and the knob-shaped structural elements 9.

In contrast to preceding embodiment variants of the cooling device 1, the knob-shaped structural elements 9 do not consists of a plastic but rather of glass, meaning they are glass elements. These glass elements are made from a glass powder, in particular, using a sintering method. For this purpose, a glass powder is preferably used, whose size is between 25 μm and 250 μm, in particular between 50 μm and 150 μm. However, glass powders having different grain sizes may also be used.

Generally, porously designed knob-shaped structural elements 9 are preferred. As mentioned before, these may be formed by glass elements. However, they may also consist of other materials, for example be designed as ceramics elements or as sintered copper elements.

In general, the porosity of the knob-shaped structural elements 9 may amount to between 5% and 50%, in particular between 10% and 30%. In this regard, porosity refers to the relation of cavity volume to the overall volume of the structural elements 9. The porosity can be measured, for example, using a porosimeter or by Archimedes' water displacement method.

The pores of the porous knob-shaped structural elements 9 may have a maximum diameter of between 50 μm and 250 μm, in particular between 75 μm and 150 μm.

The sintering process causes porous structural elements 9, which contribute to the capillary fluid transport inside the cooling device 1. These may therefore act as capillary pumps. Like in the preceding embodiment variants of the cooling device 1, these structural elements 9 are in contact, in particular in direct contact, with the plies or layers of the cooling device 1 arranged, in each case, below and above them for the vertical fluid transport and/or heat transfer.

In this embodiment variant of the cooling device 1, the knob-shaped structural elements 9 preferably have an at least approximately mushroom-shaped habitus. The maximum diameter 10 of these structural elements may be selected from a range of 3 mm to 20 mm, in particular from a range of 5 mm to 15 mm. Regarding the height 11 of and the maximum distance 12 between the knob-shaped structural elements 9, it is pointed to preceding relevant explanations.

The knob-shaped structural elements 9 of this embodiment variant are not connected to one another but are individual elements. In order to be able to handle them better, the holding element 8 is equipped with recesses and/or openings 16, wherein one structural element 9 is inserted into each of them. In this regard, the maximum diameter of the openings 16 is preferably smaller than the maximum diameter of the structural elements 9 so that while they can be inserted into the openings 16, they lie on top of the holding element 8 with the “mushroom head”.

In general, the knob-shaped structural elements 9 may have a shape allowing them to be arranged to both project into the opening 16 and lie on top of the holding element 8. For example, they may have a support surface extending around the circumference at least in some sections, like the structural elements 9 shown in FIG. 5. This support surface may be formed, for example on a web or a cross-section expansion, for example a step-shaped offset.

In this context, it should be noted by way of explanation that the knob-shaped structural elements 9 do not have to be knob-shaped in themselves, but that the “knob-shape” is to be seen in interaction with the holding element 8. Thus, the vaporization element 4 as a whole comprises the knobbed shape of the surface.

The holding element 8 is preferably designed to be plate-shaped according to an embodiment variant of the cooling device 1. Moreover, the shape of the openings 16 is preferably adapted to the shape of the structural elements 9. For example, the openings 16 may be designed to be circular if the structural elements 9 have a cylindrical section, which is inserted into and/or stuck through the openings 16.

Moreover, the holding element 8 preferably consists of a polymer material, in particular a plastic, preferably selected from the aforementioned plastics, for example PE. According to a further embodiment variant, it may be provided in this regard that the polymer material is a hydrophilic plastic, for example a polyamide (e.g. PA 6, PEI). Instead of using a hydrophilic plastic, it is also possible to use a hydrophobic plastic, which has a hydrophilic coating or the surface of which was made hydrophilic, for example was fluorinated. In general, a plastic may be used for this embodiment variant, which has a polar surface, wherein the wetting angle for water amounts to between 0° and 45°, in particular between 0° and 20°. The measurement of the contact angle is carried out based on the method mentioned in DIN 55660-2: 2011-12.

According to a further embodiment variant of the cooling device 1, the holding element 8 may be connected to the mat 13 by use of connecting elements 17, which are, for example, arranged in the corner regions of the holding element. According to a further embodiment variant, the mat 13 may additionally also have corresponding recesses and/or openings 18, into and/or through which the connecting elements 17 can be inserted and/or stuck.

According to a different embodiment variant of the cooling device 1, it may be provided that a plastic element 19 is arranged between the sleeve 2 and the vaporization element 4, in particular between the mat 13 and the first film 5, which plastic element 19 particularly consists of a hydrophilic polymer material and/or a polymer material having a hydrophilic surface. Regarding hydrophilicity, the preceding explanations are pointed to.

The plastic element 19 is preferably made of PA or PE.

The plastic element 19 is in particular designed to be plate-shaped and preferably has an areal extent which is at least approximately as large as that of the mat 13 or of the vaporization element 4.

In this context, it is pointed out that in the embodiment variant of the cooling device 1 according to FIG. 5, the vaporization element 4 has an areal extent which is at least approximately as large as that of the mat 13, in each case as viewed from the top.

In general, the plastic element 19 and/or the holding element 8 may have a thickness selected from a range of 0.4 mm to 4 mm, in particular from a range of 0.5 mm to 1 mm in all embodiment variants of the cooling device 1.

As an alternative to the plastic element 19, the first film 5 of the sleeve may have a layer with hydrophilic properties, wherein the layer is the innermost layer, i.e. the one facing the interior 3, of the first film 5. This also allows achieving the effect of the arrangement of the plastic element 19, namely the formation of a capillary channel between the holding element 8 and the plastic element 19.

It is further possible that, instead of the plastic element 19, a metal plate and/or metal layer is used, in particular a copper plate and/or copper layer.

The mat 13 preferably directly abuts on the knob-shaped structural elements 9, in particular on their bottom side, which faces the first film 5 of the sleeve 2. Hence, the fluid transport can be improved.

According to an embodiment variant of the cooling device 1 according to FIG. 5, it may also be provided that a mat 13 made of or comprising inorganic fibers is arranged on the upper side of the knob-shaped structural elements 9 (in particular immediately abutting on the structural elements 9), that is that side which faces the second film 6. With this embodiment variant, the distribution of the fluid (the working medium in the liquid state) from the structural elements 9 across the entire area of the vaporization element 4 can be improved. In the range of condensation of the working medium in the cooling device 1, the removal of the condensed working medium can therefore be accelerated.

According to a further embodiment variant of the cooling device 1, at least one metal element 20 may be arranged between the sleeve and the vaporization element.

The metal element 20 preferably consists of copper. However, a different metal, for example aluminum, or a metal alloy, for example a copper base alloy, may also be used.

The metal element 20 may have a thickness, which is selected from a range of between 0.2 mm and 1 mm, in particular from a range of between 0.3 mm and 0.5 mm. Moreover, the metal element 20 may be preformed, for example in a tub-shape, whereby the interior 3 can be better formed. The cooling device 1 can be given, inter alia, a better mechanical stability by means of the metal element 20.

The metal element 20 may have an areal extent, which at least approximately corresponds to that of the vaporization element 4, or which is between the areal extent of the vaporization element 4 and that of the second film 6, in each case as viewed from the top.

As can be seen from FIGS. 6 and 7, the cooling device 1 may be designed to be plate-shaped or to have an L-shaped cross-section. In this regard, a cooling device 1 according to the embodiment variant of FIG. 5 is shown. These shapes of the cooling device 1, however, can also be applied to the further embodiment variants of the cooling device 1.

In the L-shaped configuration, the cooling device 1 has a vertical section 21 and a horizontal section 22. In the horizontal section 22, the absorption of heat (arrows 23) takes place by vaporization of the working medium. The gaseous working medium is then guided into the vertical section 21, in which the condensation of the working medium takes place by means of heat dissipation to the surroundings (arrows 24).

The components of the cooling device 1 are preferably arranged in the interior 3 in the heat-emitting zone, conversely to the heat-absorbing zone. This means that, for example, the metal element 20 is arranged in the heat-emitting section 21 following the first film 5 of the sleeve 2 and in the heat-absorbing section 22 following the second film 6 of the sleeve 2. In the heat-absorbing section 22, the cooling device 1 may have the sequence first film 5, plastic element 19, mat 13, holding element 8 with the structural elements 9, metal element 20, second film 6. In the heat-emitting section 21, the cooling device 1 may have the sequence first film 5, metal element 20, holding element 8 with the structural elements 9, mat 13, plastic element 19, second film 6.

It is moreover possible that a reservoir for non-condensable gases is formed in the section 21, between the structural elements 9, the holding element 8 and the plastic element 19.

FIGS. 8 and 9 show a rechargeable battery 25 with two possible arrangements of the cooling device 1 on the rechargeable battery 25. Accordingly, the L-shaped cooling device 1 may be arranged, according to FIG. 8, such that the rechargeable battery 25 stands on the horizontal section 22, and that the vertical section 21 is arranged in the region of a side wall of the rechargeable battery 25.

The plate-shaped design of the cooling device 1 may also comprise the heat-absorbing section 22 and at least one of the heat-emitting sections 21. All sections 21, 22 are arranged in one plane. The rechargeable battery 25 again stands on the heat-absorbing section 22. The two heat-emitting sections 21 are arranged so as to laterally connect to the rechargeable battery 25.

In the plate-shaped design of the cooling device 1, it is also possible that only one of the heat-emitting sections 21 is arranged. The L-shape according to FIG. 8 and/or FIG. 7 may also be modified into a U-shape with two heat-emitting sections 21.

FIG. 10 shows multiple storage modules 26 for electrical energy of the rechargeable battery 25 (FIG. 8). The cooling device 1 is again designed in an L-shape. By way of example, two cooling devices 1 and 209 storage modules 26 are shown. These specifications are not to be understood in a limiting manner for the invention but have a purely exemplary character.

The two cooling devices 1 are arranged such that the heat-emitting sections 21 are arranged so as to be next to one another, wherein one or multiple further cooling device(s) 27 (secondary cooler) is (are) arranged between these sections 21, in particular so as to directly abut on the two sections 21 of the cooling device 1.

The heat from the cooling device 1 is given off via the sections 21 to the further cooling device 27, which subsequently transports the heat out of the region of the rechargeable battery 25.

The further cooling device 27 may be a liquid cooler, as it is shown in FIG. 10, and for example be integrated into the cooling system of a vehicle.

However, it is also possible that the further cooling device 27 is an air cooler or a gas cooler, as it is shown in FIG. 11. The two embodiments are different merely because of the size of the further cooling device 27. The air or gas cooler is designed to be larger compared to the liquid cooler.

However, the further cooling device 27 may generally be an evaporative cooler (refrigerant evaporator) and/or be integrated into the circuit of an evaporative cooler (refrigerant evaporator), for example into the circuit of an air conditioner of a vehicle.

FIG. 12 shows an embodiment of the rechargeable battery 25, in which the storage modules 27 are contacted electrically via two busbars 28. Each of the two busbars 28 is cooled and/or temperature controlled by means of a cooling device 1, for which purpose the cooling devices 1 are arranged so as to abut on, in particular directly abut on, the busbars 28.

FIG. 13 shows a further embodiment variant of the cooling device 1 in a sectional side view. In this embodiment variant, a foam element 29 is arranged in the interior 3 of the sleeve 2. The mat 13 made of or comprising the inorganic fibers is again arranged between the foam element 29 and the sleeve 2, which is again preferably formed by the first and the second film 5, 6. The foam element 29 is preferably surrounded, in particular shrouded completely by the mat 13 on at least four sides. Moreover, the metal element 20 may also be arranged between the second film 6 and the mat 13.

This cooling device 1, as well, may again have multiple of these vaporization elements 4 in the interior 3, similar to the embodiment variant according to FIG. 1, wherein in this case, the multiple foam elements 29 may also each be surrounded completely by a mat 13 according to a further embodiment variant.

The foam element 29 may be a metal foam, for example a copper foam or a nickel foam, or a plastic foam, etc. In general, the foam element 29 preferably has an inherent stiffness so great that the foam element 29 is self-supporting.

The foam element 29 preferably has a porosity of at least 70%, in particular at least 80%, preferably at least 90%. In respect of measuring the porosity, it is pointed to preceding explanations in this regard.

The pores of the foam element 29 may have a maximum diameter of between 0.5 mm and 5 mm, in particular between 1 mm and 1.3 mm.

Due to the porosity, the foam element 29, in turn, provides gas channels for the gas transport. The fluid transport takes place via the mat 13.

The foam element 29 may also be designed having knob-shaped structural elements 9 (e.g. FIG. 3 or FIG. 5).

In the context of the invention, the at least one vaporization element 4 is generally preferred to be surrounded completely (on all sides) by the sleeve 2.

However, the cooling device 1 cannot only be used for cooling the storage modules 26 or the busbars of a rechargeable battery 25 but generally for cooling a rechargeable battery 25 or a rechargeable battery pack with multiple rechargeable batteries 25, or electronic components, electric motors, etc.

The exemplary embodiments show possible embodiment variants of the cooling device 1 and/or of the rechargeable battery 25, while it should be noted at this point that combinations of the individual embodiment variants are also possible.

Finally, as a matter of form, it should be noted that for ease of understanding of the structure of the cooling device 1 and/or of the rechargeable battery 25, these are not obligatorily depicted to scale.

### LIST OF REFERENCE NUMBERS

1 Cooling device

2 Sleeve

3 Interior

4 Vaporization element

5 Film

6 Film

7 Welding frame

8 Holding element

9 Structural element

10 Diameter

11 Height

12 Distance

13 Mat

14 Mat

15 Element

16 Opening

17 Connecting element

18 Opening

19 Plastic element

20 Metal element

21 Section

22 Section

23 Arrow

24 Arrow

25 Rechargeable battery

26 Storage module

27 Cooling device

28 Busbar

29 Foam element

1. A cooling device (1) comprising a sleeve (2) of at least one single-layer or multi-layer film (5, 6), which forms an interior (3), in which a working medium and at least one vaporization element (4) for converting at least part of the working medium from the liquid to the gaseous state are contained, wherein at least one mat (13) made of/comprising inorganic fibers is arranged between the vaporization element (4) and the sleeve (2), and that the vaporization element (4) has knob-shaped structural elements (9) and/or is formed as a foam element (29).

2. The cooling device (1) according to claim 1, wherein multiple vaporization elements (4) are arranged in the interior (3) of the sleeve (4).

3. The cooling device (1) according to claim 1, wherein the vaporization element (4) is made of a polymer material and formed in one piece.

4. The cooling device (1) according to claim 3, wherein a mat (14) made of/comprising inorganic fibers is arranged between the vaporization elements (4).

5. The cooling device (1) according to claim 1, wherein the knob-shaped structural elements (9) are designed to be porous, in particular are formed by glass elements or by ceramic elements or by sintered copper elements.

6. The cooling device (1) according to claim 1, wherein the vaporization element (4) has a holding element (8), in which the knob-shaped structural elements (9) are held.

7. The cooling device (1) according to claim 6, wherein the holding element (8) is designed to be plate-shaped and made of a polymer material.

8. The cooling device (1) according to claim 6, wherein the polymer material is a hydrophilic plastic.

9. The cooling device (1) according to claim 1, wherein at least one plastic element (19) made of a hydrophilic polymer material is arranged be-tween the sleeve (2) and the vaporization element (4).

10. The cooling device (1) according to claim 1, wherein at least one metal element (20) is arranged between the sleeve (2) and the vaporization element (4).

11. The cooling device (1) according to claim 1, wherein the sleeve (2) is at least partially formed by a composite film made of at least one polymer material and a metal film.

12. The cooling device (1) according to claim 1, wherein the sleeve (2) is formed by two films (5, 6) connected to one another.

13. The cooling device (1) according to claim 12, wherein the two films (5, 6) are different from one another.

14. The cooling device (1) according to claim 1, wherein it is designed to be plate-shaped or to have an L-shaped cross-section.

15. A rechargeable battery (25) having a storage module (26) or multiple storage modules (26) for electrical energy and at least one cooling device (1) for cooling or controlling the temperature of the at least one storage module (26), wherein the cooling device (1) is designed according to claim 1.

16. The rechargeable battery (25) according to claim 15, wherein the cooling device (1) is at least partially arranged between the two storage modules (26), wherein a further cooling device (27), which abuts on the cooling device (1), is arranged between the storage modules (26).

17. The rechargeable battery (25) according to claim 15, wherein the multiple storage modules (26) are connected to one another via at least one busbar (28), wherein the cooling device (1) is arranged so as to abut on the busbar (28).
